(19) United States
(12) Patent Application Publication
(10) Pub. No.: US 2009/0196088 A1
(43) Pub. Date: Aug. 6, 2009

(54) RESISTANCE CONTROL IN CONDUCTIVE BRIDGING MEMORIES

(76) Inventors: Rok Dittrich, Bruxelles (BE); Jan Keller, Voorburg (NL); Ralf Symanczyk, Munchen (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/024,300

(22) Filed: Feb. 1, 2008

(51) Int. Cl. G11C 11/00

(52) U.S. Cl. 365/148

(57) ABSTRACT

An integrated circuit may comprise one or more resistive storage cells, wherein each resistive storage cell comprises a resistive storage medium that is switchable between at least a high resistive state and a low resistive state; and a resistance element communicatively coupled to the resistive storage medium in series.

### BACKGROUND OF THE INVENTION

Resistive memories make use of a memory element that can change its electrical resistance through suitable programming. Accordingly, the memory element comprises a resistive storage medium which may form a resistive storage region of the memory and which exhibits at least two different states having different electrical resistance. One of these states may be referred to as a high resistive state or an OFF state and the other may be referred to as a low resistive state or ON state, where the electrical resistance of the ON state may be lower than that of the OFF state. The resistive storage medium may be switched between these states through suitable programming.

### BRIEF DESCRIPTION OF THE DRAWINGS

Details of one or more implementations are set forth in the accompanying drawings and description below. Other features will be apparent from the description and drawings, and from the claims.

FIGS. 1A to 1D show examples of resistive storage cells according to an embodiment.

FIGS. 2A to 2C show examples of resistive storage cells comprising a select device according to another embodiment.

FIGS. 3A to 3B show a method of operating a resistive storage medium in accordance with a WRITE operation according to an embodiment.

FIGS. 4A to 4B show a method of operating a resistive storage medium in accordance with a ERASE operation according to another embodiment.

FIGS. 5A to 5B show examples of integrated circuits comprising resistive storage cells with a common plate.

FIG. 6 shows a system according to one embodiment.

### DETAILED DESCRIPTION OF THE PREFERRED EMBODIMENT

Embodiments disclosed herein are generally directed to conductive bridging cells, particularly to resistance control in a conductive bridging memory.

In one embodiment, a memory element may have at least one high resistive state and at least one low resistive state. In one embodiment, a ratio of a resistance of the at least one high resistive state relative to the resistance of the at least one low resistive state may be at least 10, for example. In another embodiment, this ratio may be at least 100. In yet another embodiment, this ratio may be at least 1000 or even more than 10⁴ or more than 10⁵. A high ratio makes it easier to distinguish between the two states when electrically detecting them. Nevertheless, the storage medium is not limited to these examples. In a further embodiment, said resistance ratio may even be smaller than 10. Moreover, in addition to the at least one high resistive state and the at least one low resistive state additional resistive states may exist with a resistance between the at least one high resistive state and the at least one low resistive state. Such state may be particularly applied for multi-level storage cells, for example.

Depending on the applied material for the storage medium and the applied switching mechanism, programming may comprise the application of a thermal, electrical, magnetic, optic, etc. treatment of the storage medium, for example. In one embodiment, a storage medium may be switched or programmed by applying an electrical treatment, i.e. by applying a current or a voltage, such as a current pulse or voltage pulse, for example, to the storage medium. This electrical programming signal may be applied via a first electrode and a second electrode that are electrically connected to the storage medium.

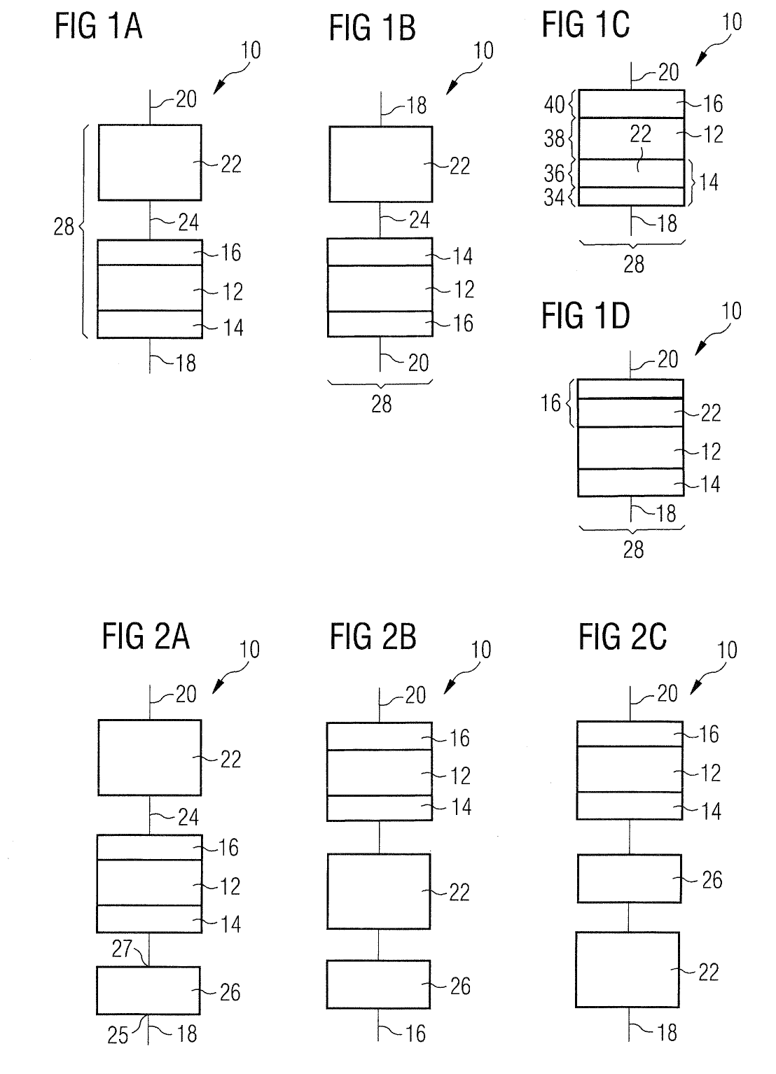

FIG. 1A shows an embodiment of an integrated circuit 10 that may be implemented as a conductive bridging (CB) cell. According to this embodiment, the integrated circuit comprises a storage cell 28 that may form a polar storage cell. The integrated circuit 10, particularly the resistive storage cell 28, comprises a resistive storage medium 12 that may be electrically contacted via a first electrode 14 and a second electrode 16. In the example of FIG. 1A, the resistive storage medium 12 may comprise a solid state electrolyte material that may be switchable between an OFF state and an ON state through the application of an electrical voltage or an electrical current. The resistive storage medium 12 may comprise metal doped chalcogenide material, such as Ag-doped GeS, for example. Nevertheless, the integrated circuit 10 is not limited to this material. In other embodiments, the resistive storage medium 12 may comprise other switchable material, particularly other chalcogenide material, such as GeSe, AsS, WO, AsSe, CuS, and/or ternary compounds, such as GeSSe, for example, or combinations thereof may be applied for the resistive storage medium 12. Moreover, the switchable material is not limited to the any specific stoichiometry of the compounds. Instead, the any suitable stoichiometry may be selected depending on the desired application and switching properties. Moreover, the resistive storage medium 12 may be doped with another metal, such as Cu, for example.

As shown in FIG. 1A, a first electrode 14 and a second electrode 16 may be arranged at the resistive storage medium 12. The first electrode 14 and the second electrode 16 may be electrically connected to the resistive storage medium 12. In the embodiment shown in FIG. 1A, the resistive storage medium 12 is sandwiched between the first electrode 14 and the second electrode 16. Moreover, the first electrode 14 and/or the second electrode 16 may be electrically contacted directly or indirectly via a first electrical cell connection 18 and/or a second electrical cell connection 20, respectively.

The integrated circuit 10, and particularly the conductive bridging cell 28 shown in FIG. 1A, comprises a resistance element 22 which is electrically connected in series to the resistive storage medium between the first electrical cell connection 18 and the second electrical cell connection 20, which may be referred to as a first and a second terminal, respectively, in this example. In the particular example of FIG. 1A, the resistance element 22 is electrically interposed between the second electrode 16 and the second electrical cell connection 20, i.e. the second electrode 16 is indirectly contacted to the second electrical cell connection 20 via the resistance element 22.

In one embodiment, the resistive storage medium 12 may be switched from an OFF state to an ON state by applying an electrical voltage between the first electrode 14 and the second electrode 16. This switching process may be referred to as a WRITE operation. In particular, an electrical WRITE pulse may be applied via the first electrical cell connection 18 and the second electrical cell connection 20. This WRITE pulse may be applied as an electrical WRITE voltage V_{W} that is greater than a threshold voltage Vₜₕ.

In one embodiment, the resistive storage medium 12 may, for example, exhibit an OFF state resistance R_{OFF}, i.e. a high resistive state, between about 10⁸Ω and about 10¹²Ω. In another embodiment, the at least one OFF state resistance R_{OFF} may be at least about 100 kΩ or more than about 1 MΩ or even more than about 10 MΩ or more than about 100 MΩ. In further embodiments, the OFF state resistance R_{OFF} may be more than about 10⁹Ω or even more than about 10¹⁰Ω or 10¹¹Ω or even more than about 10¹²Ω.

In one embodiment, the first electrode 14 may be an inert electrode and the second electrode 16 may be a reactive electrode. An inert electrode 16 may comprise tungsten (W). A reactive electrode 18 may comprise silver (Ag) or copper (Cu), for example. In one embodiment, the reactive electrode may comprise the same material as the metal-doping of the resistive storage medium 12. Nevertheless, the electrodes are not limited to these materials but also other materials may be applied. In another embodiment, other electrode material, such as Ti, Ta, Au, Si, TaN, TiN or combinations thereof may be applied for the inert electrode. In yet another embodiment, Zn and/or a multi-layer or an alloy comprising reactive and inert material, such as AgTa, AgTi, CuRu/AgTa, for example, may be applied for the reactive electrodes.

Moreover, in one embodiment the resistance element 22 may exhibit a resistance R_{S} that is smaller than the OFF state resistance R_{OFF} of the resistive storage medium 12. In one embodiment, the resistance R_{S} of the resistance element 22 may be at least a factor of 10, or even a factor of more than 100 smaller that the OFF state resistance R_{OFF} of the resistive storage medium 12. In another embodiment, the resistance element 22 may exhibit a resistance R_{S} between about 10⁴Ω and about 10⁸Ω, or between about 10⁵Ω and about 10⁷Ω.

In another embodiment, the resistance R_{S} of the resistance element may be at about 500 kΩ. The resistance element may comprise silicon, such as doped silicon, for example, or silicide, or metal-nitride, of poly-silicon, or W, or Al, for example.

According to one embodiment, the electrical voltage during the WRITE operation, i.e. the electrical WRITE pulse, may have a first polarity such that the reactive electrode 16 is applied as anode, i.e. the positive pole is connected to the second electrical cell connection 20 while the negative pole is connected to the first electrical cell connection 18.

Accordingly, in one embodiment, a method of operating the resistive storage medium 12 may comprise applying an electrical operation signal between a first terminal, such as the first electrical cell connection 18, for example, and a second terminal, such as the second electrical cell connection 20, for example, of a memory cell, such as the storage cell 28, for example, comprising the resistive storage medium 12, with the resistance element 22 of the memory cell being electrically connected in series to the resistive storage medium 12 between the first terminal and the second terminal.

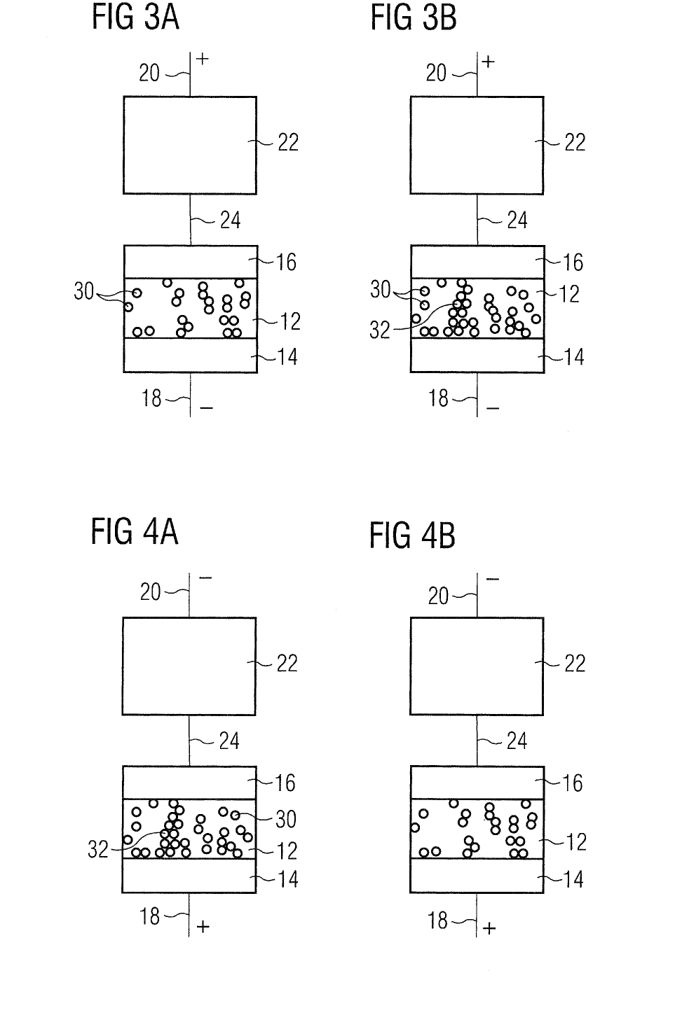

FIGS. 3A to 4B demonstrate methods of operating a resistive storage medium according to an embodiment. Accordingly, in one embodiment, a method comprises providing the memory cell, such as the resistive storage cell 28, with a first terminal, such as the first electrical cell connection 18, a second terminal, such as the second electrical cell connection 20, and the resistance element 22 electrically connected in series with the resistive storage medium 12 between the first terminal and the second terminal.

FIG. 3A and FIG. 3B demonstrate a method of operating the resistive storage medium 12 comprised in the resistive storage cell 28 of FIG. 1A according to an embodiment. According to this embodiment, applying the electrical operation signal between the first terminal 18 and the second terminal 20 may comprise applying an electrical WRITE pulse such as a WRITE voltage, for example, with a WRITE polarity (indicated by a “+” and a “−” sign in FIG. 3A) such that the reactive electrode 16 contacting the resistive storage medium 12 is positively biased with respect to the inert electrode 14 contacting the resistive storage medium 12. Particularly, a predetermined voltage that is greater than a threshold voltage Vₜₕ may be applied to the serial connection of the resistance element 22 and the resistive storage medium 12. This operation may be referred to as a WRITE operation.

Through this applied voltage during the WRITE operation, metal ions 30, such as Ag⁺, for example, may be generated by a redox reaction at the reactive electrode 16. The electrical field resulting from the applied voltage may cause an injection of the metal-ions 30 from the anode 16 and an electron current from the cathode 14 reduces an equivalent number of metal-ions 30 as injected from the anode 16, thereby forming in the resistive storage medium metal-rich electro-deposits 32 (as shown in FIG. 3B). The magnitude and duration of the ion current may determine the amount of metal deposited and hence the conductivity of the resistive storage medium 12. In particular, the application of the WRITE pulse or WRITE voltage may lead to the formation of metal-rich clusters, which form at least one electrically conductive bridge 32 between the first electrode 14 and the second electrode 16, as shown in FIG. 3B. Once the electrically conductive bridge 32 is formed, the electrical resistance of the resistive storage medium 12 drops to a low resistive state corresponding to an ON state of the resistive storage medium 12.

The resistive storage medium 12 may, for example, exhibit an ON state resistance R_{ON}, i.e. a low resistive state, between about 10²Ω and about 10⁶Ω. In another embodiment, an ON state resistance R_{ON} of the resistive storage medium 12 may be between about 10³Ω and about 10⁵Ω. Nevertheless, the resistive storage medium 12 is not limited to these resistance values for a resistive ON state. In other embodiments the ON state resistance R_{ON} may be less than about 1 MΩ, or even less than about 100 kΩ or less than about 10 kΩ. In further embodiments, the ON state resistance R_{ON} may be below about 1 kΩ, or even below about 0.1 kΩ.

In one embodiment, the resistance element 22 may exhibit a resistance R_{S} that is greater than an ON state resistance R_{ON} of the resistive storage medium 12. In one example, the resistance R_{S} of the resistance element 22 may be at least a factor of 10, or even a factor of more than 100 greater than an ON state resistance R_{ON} of the resistive storage medium 12. According to one embodiment, the resistance R_{S} of the resistance element 22 may be between an ON state resistance R_{ON} and an OFF state resistance R_{OFF} of the resistive storage medium 12.

In some embodiments, for subsequent WRITE operations the ON state resistance R_{ON} may fluctuate, i.e. the ON state resistances R_{ON} in subsequent WRITE operations may differ from one another. In some cases, R_{ON} may fluctuate by a factor of more than about 2, or more than about 5, or even more than about 10. In some particular cases, even fluctuations of the ON state resistance R_{ON} between different WRITE operations by a factor of up to 50 or 100 may occur.

At the beginning of the WRITE operation, i.e. when the resistive storage medium is in a high resistive state (OFF state), as shown in FIG. 3A, the electrical resistance of the series connection of the resistive storage medium 12 and the resistance element 22 may be largely determined by the OFF state resistance R_{OFF} of the resistive storage medium 12, i.e. the electrical resistance between the first electrical cell connection 18 and the second electrical cell connection 20 may be largely determined or dominated by the OFF state resistance R_{OFF} that may be larger than the resistance R_{S} of the resistance element 22. Accordingly, a WRITE voltage V_{W} applied between the first electrical cell connection 18 and the second electrical cell connection 20 may largely drop at the resistive storage medium 12, thereby causing the formation of the electrically conductive bridge 32 between the first electrode 14 and the second electrode 16, as shown in FIG. 3B.

Once the electrically conductive bridge is formed, the electrical resistance of the resistive storage medium 12 drops to a low resistive state corresponding to an ON state resistance R_{ON} of the resistive storage medium 12, which may be smaller than the resistance R_{S} of the resistance element 22. Accordingly, once the resistive storage medium is switched to an ON state, the electrical resistance of the series connection of the resistive storage medium 12 and the resistance element 22 may be largely determined by the resistance R_{S} of the resistance element 22. Accordingly, the electrical resistance between the first electrical cell connection 18 and the second electrical cell connection 20 may be largely determined or dominated by the resistance R_{S} of the resistance element 22, which may be larger than the resistance R_{ON} of the resistive storage medium 12. Thus, the fluctuations of the electrical resistance between the first and second electrical cell connection 18, 20 in subsequent WRITE operations is largely reduced as compared to the above mentioned fluctuations of the ON state resistance R_{ON} of the resistive storage medium 12.

Accordingly, in one embodiment the method may comprise forming at least one electrically conductive pathway, such as the electrically conductive bridge 32 shown in FIG. 3B, within the resistive storage medium 12 between the reactive electrode 16 and the inert electrode 14. Forming the at least one electrically conductive pathway 32 may, particularly, comprise reducing an electrical resistance of the resistive storage medium 12 from a value greater than an electrical resistance R_{S} of the resistance element 22 to a value close to or smaller than the electrical resistance R_{S} of the resistance element 22.

As shown in FIG. 4A and FIG. 4B, in a further embodiment, the resistive storage medium 12 may be switched from an ON state (FIG. 4A) to an OFF state (FIG. 4B) by applying an electrical voltage between the first electrode 14 and a second electrode 16 or by driving an electrical current through the resistive storage medium 12 via the first 14 and second electrode 16. This switching process may be referred to as an ERASE operation. In particular, an electrical ERASE pulse may be applied via the first electrical cell connection 18 and the second electrical cell connection 20. This ERASE pulse may be applied as an electrical ERASE voltage V_{E}. The electrical ERASE pulse is accompanied by a current through the resistive storage medium 12. In one embodiment, the ERASE pulse may be applied with a second polarity opposite to the first polarity. This may result in a reverse ion current flow until the previously injected metal, such as Ag, for example, has been at least partly oxidized (e.g. Ag->Ag⁺+e⁻) and at least partly deposited back to the electrode 16 which supplied the metal. Thereby the at least one conductive bridge 32 is removed, and, thus, the resistivity increases again and an OFF state resistance R_{OFF} may be achieved for the resistive storage medium 12 that may be larger than the resistance R_{S} of the resistance element 22, i.e. R_{OFF}>R_{S}. Accordingly, at least two different resistive states of the first electrical cell connection 18 and the second electrical cell connection 20 may be distinguishable.

Accordingly, in one embodiment of a method of operating the resistive storage medium 12, applying the electrical operation signal between the first terminal 18 and the second terminal 20 may comprise applying an electrical ERASE pulse with an ERASE polarity such that the reactive electrode 16 contacting the resistive storage medium 12 is negatively biased with respect to the inert electrode 14 contacting the resistive storage medium 12. In particular, the method may comprise at least partly removing the electrically conductive pathway 32 within the resistive storage medium 12 between the reactive electrode 16 and the inert electrode 14.

Due to the operation principle a storage cell based on this technology may be called a Programmable Metallization Cell (PMC). Accordingly, in one embodiment, an integrated circuit such as the integrated circuit 10 of FIG. 1A may be applied as a non-volatile memory cell, where the resistive storage medium 12 remains in its resistance state (ON state or OFF state) without requiring refresh pulses or cycles, even without a power supply.

As explained above, the serial connection of the resistive storage medium 12 and the resistance element 22 may reduce the fluctuations of the electrical resistance between the first 18 and second electrical cell connection 20 in the ON states of the resistive storage medium 12 as compared to the fluctuations of the ON state resistance R_{ON} of the resistive storage medium 12, itself. Accordingly, in particular when applying the integrated circuit 10 as a storage cell 28 or a storage device, an ON state resistance of the storage cell 28, which comprises the resistive storage medium 12 and the resistance element 22, may be largely determined by the resistance R_{S} of the resistance element 22 and, therefore, fluctuations may be reduced. Accordingly, a READ operation of the stored information, i.e. a determination of the cell resistance may be easier. Moreover, due to a narrow distribution of the ON state resistance of the storage cell 28, an ERASE operation may be performed as a voltage controlled process, where a predetermined voltage may be applied between the first electrical cell connection 18 and the second electrical cell connection 20, while the resulting current is largely independent of the ON state resistance R_{ON} of the resistive storage medium 12. This may allow an easy, reliable, and secure operation of the integrated circuit 10.

According to one embodiment of a method of operating the resistive storage medium 12, which may be referred to as a READ operation, applying the electrical operation signal between the first terminal 18 and the second terminal 20 comprises applying an electrical READ signal, such that a voltage drop across the resistive storage medium 12 is smaller than a threshold voltage Vₜₕ for switching the resistive storage medium between the at least one high resistive state and the at least one low resistive state, for example. The method may further comprise determining a resistance state of an electrical resistance between the first and second terminal 18, 20.

In this connection, it is not required that a precise resistance of the resistive storage medium 12 is measured. Instead, in one embodiment only a resistance state between the first and second terminal 18, 20 may be determined. Nevertheless, in this embodiment it also not required that a precise resistance value between the first and second terminal 18, 20 is measured. In one particular embodiment, it may be detected whether the resistance between the first and second terminal 18, 20 is considerably higher than the resistance value R_{S} of the resistance element 22 or not. This determination may be performed by comparison of the resistance between the first and second terminal 18, 20 with a resistance value of a reference resistance element. Comparing resistance values may be performed by comparing currents flowing through the reference resistance element, on the one hand, and the first and second terminal 18, 20, on the other hand, while applying a READ voltage, for example.

A determined value of the resistance of the memory cell 28, i.e. a value of the resistance between the first and second terminal 18, 20, that is considerably larger than the resistance R_{S} of the resistance element 22 may be assigned to or referred to as an “OFF” state of the memory cell 28, while a resistance of the memory cell 28 that is close to the resistance R_{S} of the resistance element 22 may be assigned to or referred to as an “ON” state of the memory cell 28.

In one embodiment, the electrical READ signal may be applied with a READ polarity such that the reactive electrode 16 contacting the resistive storage medium 12 is positively biased with respect to the inert electrode 14 contacting the resistive storage medium 12. In one embodiment, the READ signal may be applied with the WRITE polarity such that a voltage drop across the resistive storage medium 12 is smaller than the threshold voltage Vₜₕ for switching the resistive storage medium from the high resistive state to the low resistive state. Particularly, a READ voltage V_{R} may be applied between the first and second terminal 18, 20 that is smaller than said threshold voltage Vₜₕ. Accordingly, for a schematic principle of a READ operation in an “OFF” state of the storage cell 28 it may also be referred to FIG. 3A, while FIG. 3B may be considered as visualizing a schematic principle of a READ operation in an “ON” state of the storage cell 28, where in the READ operation the READ voltage V_{R} may be applied to the first and second terminal 18, 20 instead of the WRITE voltage V_{W}, for example. In another embodiment, the electrical READ signal may be applied such that the reactive electrode 16 contacting the resistive storage medium 12 is negatively biased with respect to the inert electrode 14.

Accordingly, in one embodiment, a distribution variation of the resistance of a programmed state or “ON” state of a non-volatile memory using CBRAM technology may be reduced. In another embodiment, an “ON” state resistance may be precisely tuned, independent of the resistive storage material. In yet another embodiment, the integrated circuit may provide self-protection for the resistive storage medium due to a provision of a minimum resistance of a storage cell, i.e. a limitation of a current, in particular during a programming operation. Moreover, in another embodiment, freedom of circuit design may be increased though allowing various operation modes, such as a current controlled operation mode (I-mode) or a voltage controlled operation mode (V-mode) for example.

FIG. 1B shows another embodiment of an integrated circuit 10. Similar, the example of FIG. 1A, the resistance element 22 is electrically connected in series to the resistive storage medium 12 between the first electrical cell connection 18 and the second electrical cell connection 20. In the example of FIG. 1B, however, the resistance element 22 is electrically interposed between the first electrode or inert electrode 14 and the first electrical cell connection 18, i.e. the first electrode 14 is indirectly contacted to the second electrical cell connection 20 via the resistance element 22. For further details about the individual components and their relation it is referred to the respective description of the FIG. 1A, above, where the corresponding elements are referenced with identical reference signs. In one embodiment, also the operation of the resistive storage medium 12 according to FIG. 1B may be analogous to the description of FIGS. 3A to 4B, above.

In one embodiment not directly shown but similar to the example of FIGS. 1A and 1B, the resistance element 22 may be directly arranged at the first electrode 14 or the second electrode 16. In another embodiment, the resistance element 22 may be electrically connected to the first electrode 14 or the second electrode 16 via an electrical interconnection 24 as shown in FIGS. 1A and 1B. The electrical interconnection 24 may be formed by a VIA conductor or an interconnection line of a structured metallization layer in an integrated circuit, for example.

FIG. 1C shows another integrated circuit 10, where the resistance element 22 is at least partly comprised in the first electrode 14, which may be formed as the inert electrode according to another embodiment. According to this embodiment, the integrated circuit 10 may comprise a cell stack that is electrically connected via the first 18 and second electrical cell connections 20. As shown in FIG. 1C, the cell stack may comprise a stacked layer sequence, where the resistive storage medium 12 is sandwiched between the resistance element 22 and the second electrode 16. In particular, the stacked layer sequence according to this embodiment comprises a first electrode layer 34 forming at least part of the first electrode 14, a resistive layer 36 forming at least part of the resistance element 22, a resistive storage layer 38 comprising the resistive storage medium 12, and a second electrode layer 40 forming at least part of the second electrode 16. In this embodiment, the resistance element 22 may form at least part of the inert electrode 14.

FIG. 1D shows another embodiment of an integrated circuit 10. In this example, the resistance element 22 is as least partly comprised in the second electrode 16, where the second electrode 16 may be formed as the reactive electrode. According to this embodiment, the resistive storage medium 12 may be sandwiched between the first electrode 14 and the resistance element 22, i.e. the resistance element 22 may form at least part of the reactive electrode 16. The description of the FIG. 1C in view of the structure of storage cell 28 as a stacked layer sequence may analogously apply to the example of FIG. 1D, and also to the examples of FIG. 1A and FIG. 1B, above.

Accordingly, the integrated circuit 10 may comprise one or more resistive storage cells, such as the resistive storage cell 28. Each resistive storage cell may comprise a resistive storage medium, such as the resistive storage medium 12 described herein that is switchable between at least one high resistive state and at least one low resistive state. Moreover, the resistive storage cell may comprise a resistance element, such as the resistance element 22 described herein, that is serially connected to the resistive storage medium.

In one embodiment, the resistive storage medium may comprise a solid state electrolyte material arranged between a first electrode and a second electrode. The resistive storage medium may comprise a metal-doped solid state electrolyte material, for example. Accordingly, the resistive storage medium, such as the resistive storage medium 12 described herein, may form at least part of a solid state ionic memory element which may form a polar memory element with a WRITE and an ERASE signal having opposite polarity. The resistive storage medium may particularly comprise metal-doped chalcogenide material. One of first and second electrodes 14, 16 may be formed as a reactive electrode, such as the reactive electrode 16 described herein, that may comprise a metal that is also comprised in the resistive storage medium as dopant of the metal-doped solid state electrolyte material.

According to one embodiment, the resistance element, such as the resistance element 22 described herein, may exhibit an ohmic resistance. Particularly, the resistance element may exhibit substantially the same electrical resistance for both polarities of applied voltages, for example. Moreover, the resistive storage medium may be switchable within an operation voltage range and the electrical resistance element may exhibit a substantially ohmic behavior, i.e. a substantially constant resistance, for applied voltage within the operation voltage range. In one example, the operation voltage range may be between about −1.5V and 1.5V, for example. A set voltage or WRITE voltage V_{W} may be between about 0.2V and 0.5V, particularly at about 0.3V, for example. A reset voltage or ERASE voltage V_{E} may be between about 0.05V and about 0.15V, particularly at about 0.1V, for example. Nevertheless, depending on the particular materials applied for the electrodes, the resistive storage medium and/or the resistance element, for example, also other voltages may be applied.

According to another embodiment, the storage cell 28 may comprise a stacked arrangement of the first and second electrode, the resistive storage medium and the resistance element, such as the stacked layer sequence described in connection with FIGS. 1A to 1D above, for example. Nevertheless, the integrated circuit 10 is not limited to a particular order of these elements or components. In one embodiment, the resistive storage medium may be arranged somewhere between the first and second electrode, wherein “between” (i.e. electrically connected between the first and second electrode).

In another embodiment, a resistive storage medium, such as the resistive storage medium 12 describe above, of more than one resistive storage cell may be comprised in or formed by a common resistive storage layer such as the resistive storage layer 38 describe above. In another embodiment, a resistance element, such as the resistance element 22 described above, of more than one resistive storage cell may be formed as at least part of a common resistive layer, such as the resistive layer 36 described above, for example. According to yet another embodiment, one or more of the first and second electrode, such as the electrodes 14, 16 described above, of more than one resistive storage cell may be comprised in or formed by a common electrode layer, such as the electrode layer 40, for example.

FIGS. 2A to 2C show further embodiments of an integrated circuit 10. As shown in connection with these examples, the integrated circuit 10 may comprise a select device 26 that is electrically connected in series to the resistive storage medium 12 and the resistance element 22. Accordingly, the select device 26 may comprise at least two connection regions or connection terminals 25, 27 via which the select device 26 is electrically connected for allowing a current flow through the series connection of the select device 26, the resistive storage medium 12 and the resistance element 22. In particular, the select device 26 may selectively allow or prevent current flow through the connection terminals 25, 27. This may be achieved by selectively changing a resistance or a differential resistance of the select device by applying a predetermined voltage or electrical potential to the connection terminals 25, 27 and/or an additional control terminal, for example.

Accordingly, in one embodiment the select device 26 may comprise a field effect transistor, where source and drain contacts of the field effect transistor may form the at least two connection terminals 25, 27. Depending on an electrical potential applied to a gate contact as the additional control terminal of the field effect transistor a channel conductance can be changed, thereby selectively allowing or preventing current flow between the connection terminals 25, 27 (source/drain contacts). In another embodiment, the select device 26 may comprise a diode, where the anode and cathode of the diode may form the at least two connection terminals 25, 27 of the select device 26.

Accordingly, in one embodiment the select device 26 may exhibit a selection state and a non-selection state where an electrical resistance or differential electrical resistance R₁ in the selection state may be smaller than the electrical resistance or differential resistance R₀ in the non-selection state of the select device 26. In one particular embodiment, the resistance element 22 may exhibit a resistance value R_{S} between the selection state resistance or differential resistance R₁ and the non-selection state resistance or differential resistance R₀. According to yet another additional or alternative embodiment, the OFF state resistance R_{OFF} of the resistive storage medium 12 may be between the selection state resistance or differential resistance R₁ and the non-selection state resistance or differential resistance R₀ of the select device 26.

In one embodiment, the integrated circuit 10 may form at least one memory cell in a storage device, where the select device 26 may be applied to selectively address at least one cell among a plurality of cells for READ, WRITE, or ERASE operation to be carried out at said at least one cell, for example. Accordingly, in yet another example the select device 26 may comprise any other select circuit suitable for selecting one or more cells among a plurality of cells in a storage device, such as a random access memory (RAM).

In the embodiment shown in FIG. 2A, the resistive storage medium 12 together with the first electrode 14 and the second electrode 16 is electrically connected between the resistance element 22 and the select device 26, i.e. the resistance element 22 may be electrically connected to one of the first 14 and second electrode 16, while the select device 26 may be electrically connected to the other of the first 14 and second electrode 16.

In another embodiment, shown in FIG. 2B, the resistance element 22 is electrically connected between the resistive storage medium 12 and the select device 26, i.e. the select device is indirectly connected to one of the first 14 and second electrode 16 via the resistance element 22. In yet another example, shown in FIG. 2C, the select device 26 may be electrically connected between the resistive storage medium 12 and the resistance element 22, i.e. one of the connection terminals (e.g. connection terminal 27) of the select device 26 is electrically connected to one of the first 14 and second electrode 16, while the other of the connection terminals (e.g. connection terminal 25) of the select device 26 is electrically connected to the resistance element 22.

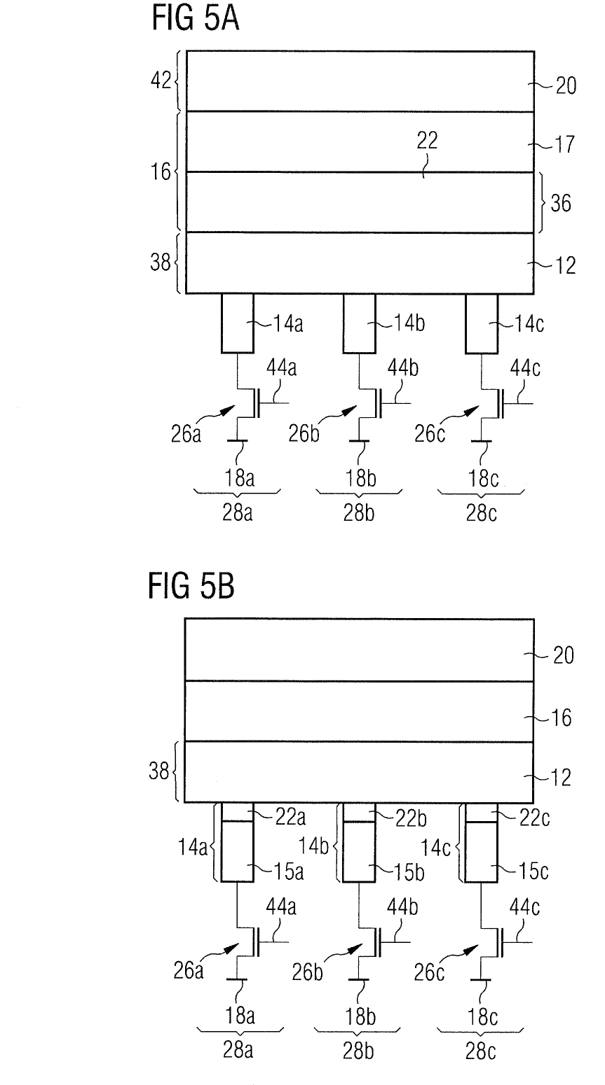

Further embodiments of an integrated circuit 10 are described in connection with FIGS. 5A and 5B. According to these embodiments, the integrated circuit 10 may be applied or implemented as a storage device comprising a plurality of storage cells 28a, 28b, 28c which may be constructed according to one of the storage cells 28 described above. In particular, the integrated circuit 10 may comprise a random access memory (RAM), for example.

In the example of FIG. 5A the storage cells 28a, 28b, 28c may be electrically constructed in accordance with the principle of FIG. 1D. In particular, in this example, the resistance element 22 may be comprised in the second electrode 16 which is a reactive electrode of a programmable metallization cell, for example. As shown in FIG. 5A, the integrated circuit comprises a common second electrode 16 or common reactive electrode for a plurality of storage cells 28a, 28b, 28c. Moreover, also the resistive storage medium 12 of said plurality of storage cells 28a, 28b, 28c may be formed as a common resistive storage layer 38. In particular, the resistive storage layer 38 may extend beyond a single storage cell and may form a resistive storage medium for more than one storage cell. Particularly, the resistive storage layer may comprise a plurality of resistive storage regions for a plurality of cells, i.e. different cells may utilize different portions or regions of a single resistive storage layer.

The second electrode 16 may comprise a layer sequence with the resistance element 22 formed by a common resistive layer 36 that is arranged at the resistive storage layer 38, and a common reactive layer 17 arranged at the common resistive layer 36. The reactive layer 17 may form at least part of a common electrode layer and it may comprise reactive electrode material (e.g. metal) as described above for the reactive electrode 16.

As shown in FIG. 5A, an additional electrically conductive connection layer 42 may be arranged at the common reactive layer 17 to form the second electrical cell connection 20, for example. In another embodiment, it is not required that such additional layer is provided. In particular, the second electrical cell connection 20 may be formed by the second electrode 16, for example.

As shown in FIG. 5A, each of the storage cells 28a, 28b, 28c may comprise a separate first electrode 14a, 14b, 14c such as an inert electrode that is electrically connected to the resistive storage medium 12. This first electrode 14a, 14b, 14c may form an inert bottom electrode for each of the storage cells 28a, 28b, 28c. In one embodiment, the first electrode 14a, 14b, 14c may comprise a tungsten plug. In one embodiment, the arrangement of bottom electrodes 14a, 14b, 14c defines the arrangement of the storage cells 28a, 28b, 28c, i.e. a formation of electrically conductive bridges 32 may substantially occur and/or start at or near a selected bottom electrode 14a, 14b, 14c during a WRITE operation. In this embodiment, the second electrode 16 and/or the resistive storage medium 12 may be formed as continuous layers.

Moreover, each of the storage cells 28a, 28b, 28c comprises a select device 26a, 26b, 26c that may be formed by a field effect transistor. One of the source/drain contacts of the field effect transistor 26a, 26b, 26c may be electrically connected to the first electrode 14a, 14b, 14c while the other source/drain contact forms the first electrical cell connection 18a, 18b, 18c that may be electrically connected to a bit line of a storage device, such as a random access memory. Moreover, the field effect transistor 26a, 26b, 26c comprises a gate contact 44a, 44b, 44c that may be electrically connected to a word line of the storage device, such as the random access memory.

FIG. 5B shows another integrated circuit 10 that is implemented as a memory device comprising a plurality of storage cells 28a, 28b, 28c according to an embodiment. Each of the storage cells 28a, 28b, 28c may be implemented analogous to the example of FIG. 1C. Accordingly, for each storage cell 28a, 28b, 28c, the resistance element 22a, 22b, 22c may be comprised in the first electrode 14a, 14b, 14c which may be formed as an inert electrode of a programmable metallization cell, for example, and arranged at the resistive storage medium 12. Unlike FIG. 5A, in the example of FIG. 5B each storage cell 28a, 28b, 28c has a separate resistance element 22a, 22b, 22c. The resistive storage medium 12 is formed as a common resistive storage layer 38 similar to the example of FIG. 5A. Also the reactive electrode 16 of the plurality of storage cells 28a, 28b, 28c is formed as a common electrode layer 38. For further details, particularly referring to the select devices 26, it is referred to the respective description of FIG. 5A which applies analogously to the example of FIG. 5B.

Accordingly, in one embodiment, a memory device, such as one of the integrated circuits 10 described above, may comprise a plurality of resistive storage cells, such as one or more of the above described storage cells 28, 28a, 28b, 28c, for example, that are arranged in rows and columns of at least one array. At least some of these storage cells may comprise a resistive storage region that may be formed by a resistive storage medium 12 according to one or more of the above described examples that is switchable between at least one high resistive state and at least one low resistive state. Moreover, each of the storage cells may comprise a resistance element, such as one of the above described resistance elements, for example, that is serially connected to the resistive storage region. Furthermore, a select device, such as a select device 26 described above with reference to FIGS. 2A-2C, may be assigned to or comprised in each of the storage cells. The resistive storage region, the resistance element and the select device may be electrically connected in series in the storage cell. Moreover, for each row of the at least one array the memory device may comprise an electrically conductive word line that is electrically connected to at least some of the storage cells of even all storage cells in the respective row. Furthermore, for each column of the at least one array the memory device may comprise an electrically conductive bit line that is electrically connected to at least some of the storage cells or even all storage cells in the respective column.

According to one embodiment, for each storage cell the at least one high resistive state exhibits a first electrical resistance R_{OFF} and the at least one low resistive state exhibits a second electrical resistance R_{ON} smaller than the first electrical resistance R_{OFF}. Moreover, the resistance element of the respective storage cell may exhibit a resistance value R_{S} between the first electrical resistance R_{OFF} and the second electrical resistance R_{ON}. In another embodiment, the resistance element of all storage cells within the at least one array may exhibit substantially the same resistance value R_{S}. In particular, the resistance element may form a constant or prescribed resistor, while the resistive storage region, such as the resistive storage medium may form a switchable or variable resistor.

As described above for the integrated circuit 10, the memory device may comprise a resistive storage layer which comprises or forms the resistive storage region of more than one resistive storage cells of the memory device. For example, the resistive storage regions of all storage cells within the at least one array may be comprised in or formed by the common resistive storage layer, such as the resistive storage layer 38 shown in FIG. 1C, 1D, 5A, or 5B, for example. Nevertheless, the memory device and the integrated circuit 10 are not limited to this example. In another embodiment, each storage cell may comprise a separate resistive storage region such as a resistive storage medium described in connection with FIGS. 1 to 4, above.

In another embodiment, the memory device may comprise a common resistive layer, such as the resistive layer 36, which comprises or forms the resistance element of more than one resistive storage cells of the memory device.

In one embodiment, the resistance elements of all storage cells within the at least one array may be comprised in or formed by the common resistive layer, such as the resistive layer 36 shown in FIG. 1C, 1D, or 5A, for example. Nevertheless, the memory device and the integrated circuit 10 are not limited to this example. In another embodiment, each storage cell may comprise a separate resistance element as may be understood from FIGS. 1 to 4 and from FIG. 5B.

In yet another embodiment, the memory device may comprise a common electrode layer which comprises or forms one of the first and second electrode of more than one resistive storage cells of the memory device. In one embodiment, one of the first and second electrode of all storage cells within the at least one array are comprised in or formed by a common electrode layer analogous to the above described integrated circuit 10 as shown in FIG. 5A and FIG. 5B, for example. This common electrode or common electrode layer may be applied as a common plate for electrically connecting all storage cells to a common electrical potential.

In one embodiment, for each storage cell the select device may comprise a select transistor having a source region and a drain region via which the select transistor is connected in series to the resistive storage region and the resistance element as shown in FIGS. 5A and 5B. Moreover, for each row of the at least one array the word line may be electrically connected to at least some gate contacts of the select transistors of the memory cells in the respective row, such as the gate contacts 44a, 44b, 44c described in connection with FIGS. 5A and 5B, above.

According to another embodiment, for each storage cell the select device may comprise a diode that is electrically connected in series to the resistive storage region and the resistance element between a first electrical cell connection and a second electrical cell connection of the storage cell, such as the first 18 and second electrical cell connection 20 described above. Moreover, for each row of the at least one array the word line may be electrically connected to at least some first electrical cell connections of the storage cells in the respective row and for each column of the at least one array the bit line may be electrically connected to at least some of the second electrical cell connections of the storage cells in the respective column. In this embodiment the memory device may be implemented as a cross-point cell array.

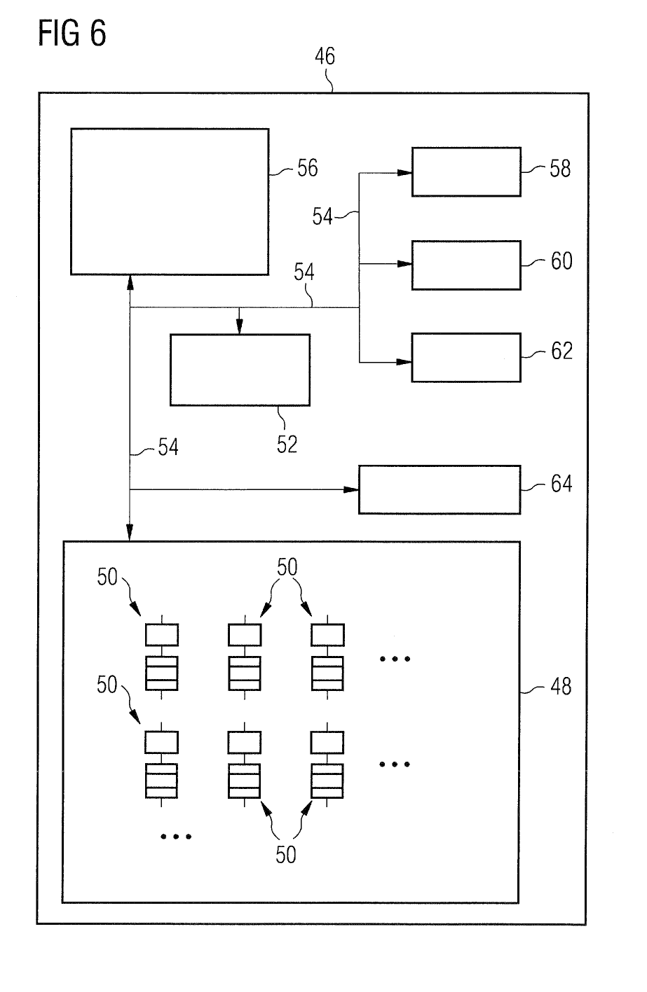

In yet another embodiment shown in FIG. 6, a system 46 or electronic device such as a computer (e.g. a mobile computer), a mobile phone, a pocket PC, a smart phone, a PDA, for example, or any kind of consumer electronic device, such as a TV, a radio, or any house hold electronic device, for example, or any kind of storage device, such as a chip card or memory card, for example, comprises one or more storage components or memories 48. The memory 48 may comprise one or more a storage cells 50. In one embodiment the at least one storage cell may be a resistive storage cell, such as one of the resistive storage cells 28, 28a, 28b, 28c described above, for example. The storage cell 50 may comprise a resistive storage medium such as the restive storage medium 12 described above, for example, that is switchable between at least a high resistive state and a low resistive state, and a resistance element, such as the resistance element 22 described above, for example, communicatively coupled to the resistive storage medium in series. In one embodiment, the memory 48 of the system 46 may comprise a plurality of storage cells arranged in rows and columns of at least one array, wherein each storage cell comprises a resistive storage region, such as one of the resistive storage regions described above, for example, switchable between at least a high resistive state and a low resistive state, a resistance element, such as one of the above described resistance elements, for example, and a select device, such as one of the above described select devices, for example. The resistive storage region, the resistance element and the select device may be communicatively coupled in series in the storage cell. In one example, the memory 48 may comprise one or more word lines for each row, the at least one word line being communicatively coupled to at least some of the storage cells 50 in the respective row. The memory 48 may further comprise one or more bit lines for each column, the at least one bit line being communicatively coupled to at least some of the storage cells 50 in the respective column.

In one embodiment, the system 46 may comprise a processing unit 52 and a system bus 54 that couples various system components including the storage component 48 to the processing unit 52. The processing unit 52 may perform arithmetic, logic and/or control operations by accessing the storage component 48, for example. The storage component 48 may store information and/or instructions for use in combination with the processing unit 52. The storage component 48 may comprise volatile and/or non-volatile memory cells 50. The storage component 48 may be implemented as a random access memory (RAM) or a read only memory (ROM), for example. In one example, a basic input/output system (BIOS) storing the basic routines that helps to transfer information between elements within the electronic device or system 46, such as during start-up, may be stored in the storage component 48. The system bus 54 may be any of several types of bus structures including a memory bus or memory controller, a peripheral bus, and a local bus using any of a variety of bus architectures.

The electronic device or system 46 may further comprise a video input and/or output device 56, such as a display interface or a display device or a camera, connected to the system bus 54, for example. Alternatively or in addition to the video device 56 the system 46 may comprise an audio device 58 for inputting and/or outputting acoustic signals, such as a speaker and/or a microphone, for example. Moreover, in one embodiment, the system 46 may comprise an input interface 60, such as input keys and/or an interface for connecting a keyboard, a joystick or a mouse, for example. In yet another embodiment, the electronic device may comprise a network interface 62 for connecting the electronic device to a wired and/or a wireless network. Furthermore, one or more additional memory components 64 may be included in the electronic device.

In one embodiment, the storage component 48 is implemented as a data memory for storing computer readable instructions, data structures, program modules and/or other data for the operation of the system 46. In another embodiment, the storage component 48 may be implemented as a graphical memory or an input/output buffer. In one embodiment the storage component 48 is fixedly connected to the system 46. In another embodiment, the storage component 48 is implemented as a removable component, such as a memory card or chip card, for example.

In general, an integrated circuit may comprise a two-terminal switching device that comprises a first terminal, a second terminal, a switchable resistor the electrical resistance of which is electrically switchable between at least one high resistive state and at least one low resistive state, and a constant resistor electrically connected in series to the switchable resistor between the first and second terminal. In one embodiment, the switching device may be a polar switching device. In this embodiment, the first terminal may be electrically connected to an inert electrode, while the second terminal may be electrically connected to a reactive electrode.

While the foregoing is directed to embodiments of the present invention, other and further embodiments of the invention may be devised without departing from the basic scope thereof, and the scope thereof is determined by the claims that follow.

What is claimed is:

1. An integrated circuit, comprising a resistive storage cell, the resistive storage cell comprising:
a resistive storage medium that is switchable between at least a high resistive state and a low resistive state; and
a resistance element communicatively coupled to the resistive storage medium in series.

2. The integrated circuit of claim 1, wherein the high resistive state exhibits a first electrical resistance R_{OFF} and the low resistive state exhibits a second electrical resistance R_{ON} smaller than the first electrical resistance R_{OFF}, and wherein the resistance element exhibits a resistance value R_{S} between the first electrical resistance R_{OFF} and the second electrical resistance R_{ON}.

3. The integrated circuit of claim 1, wherein the resistive storage medium comprises a solid state electrolyte material arranged between a first electrode and a second electrode.

4. The integrated circuit of claim 3, wherein the resistive storage medium comprises metal-doped chalcogenide material.

5. The integrated circuit of claim 4, wherein one of the first and second electrode is an inert electrode and the other of the first and second electrode is a reactive electrode, and wherein the reactive electrode comprises a metal that is also comprised in the resistive storage medium as dopant.

6. The integrated circuit of claim 1, wherein the resistance element exhibits an ohmic resistance.

7. The integrated circuit of claim 3, comprising a stacked arrangement of the first and second electrode, the resistive storage medium and the resistance element.

8. The integrated circuit of claim 7, wherein the resistance element comprises at least part of a resistive layer arranged at one of the first and second electrode.

9. The integrated circuit of claim 7, wherein the resistance element comprises at least part of a resistive layer that is arranged at the resistive storage medium and that forms at least part of one of the first and second electrode.

10. The integrated circuit of claim 1, comprising a select device electrically connected in series to the resistive storage medium and the resistance element.

11. A memory device comprising a plurality of resistive storage cells arranged in rows and columns of at least one array, wherein each storage cell comprises
a resistive storage region switchable between at least a high resistive state and a low resistive state;
a resistance element; and
a select device, wherein the resistive storage region, the resistance element and the select device are communicatively coupled in series in the storage cell, and
wherein the memory device further comprises:
a word line for each row, the word line being communicatively coupled to at least some of the storage cells in the respective row; and
a bit line for each column, the bit line being communicatively coupled to at least some of the storage cells in the respective column.

12. The memory device of claim 11, wherein for each storage cell the high resistive state exhibits a first electrical resistance R_{OFF} and the low resistive state exhibits a second electrical resistance R_{ON} smaller than the first electrical resistance R_{OFF}, and wherein the resistance element of the respective storage cell exhibits a resistance value R_{S} between the first electrical resistance R_{OFF} and the second electrical resistance R_{ON}.

13. The memory device of claim 11, wherein for each storage cell the resistive storage medium comprises a solid state electrolyte material arranged between a first electrode and a second electrode.

14. The memory device of claim 11, comprising a resistive storage layer which comprises the resistive storage region of more than one resistive storage cells.

15. The memory device of claim 11, comprising a common resistive layer which comprises the resistance element of more than one resistive storage cells.

16. The memory device of claim 13, comprising a common electrode layer which comprises one of the first and second electrode of more than one resistive storage cells.

17. The memory device of claim 11, wherein for each storage cell the select device comprises a select transistor having a source region and a drain region via which the select transistor is connected in series to the resistive storage region and the resistance element, and wherein for each row the word line is connected to at least some gate contacts of the select transistors of the memory cells in the respective row.

18. The memory device of claim 11, wherein for each storage cell the select device comprises a diode that is connected in series to the resistive storage region and the resistance element between a first electrical cell connection and a second electrical cell connection of the storage cell, and wherein for each row the word line is connected to the at least some first electrical cell connections of the storage cells in the respective row and for each column the bit line is connected to at least some of the second electrical cell connections of the storage cells in the respective column.

19. A method of operating a resistive storage medium that is switchable between at least a high resistive state and a low resistive state, the method comprising:
applying an electrical operation signal between a first terminal of a memory cell, comprising the resistive storage medium, and a second terminal of the memory cell with a resistance element of the memory cell being communicatively coupled in series to the resistive storage medium between the first terminal and the second terminal.

20. The method of claim 19, wherein applying the electrical operation signal between the first terminal and the second terminal comprises applying an electrical WRITE pulse with a polarity such that a reactive electrode contacting the resistive storage medium is positively biased with respect to an inert electrode contacting the resistive storage medium.

21. The method of claim 20, further comprising forming at least one electrically conductive pathway within the resistive storage medium between the reactive electrode and the inert electrode.

22. The method of claim 21, wherein forming the at least one electrically conductive pathway comprises reducing an electrical resistance of the resistive storage medium from a value greater than an electrical resistance of the resistance element to a value smaller than the electrical resistance of the resistance element.

23. The method of claim 19, wherein applying the electrical operation signal between the first terminal and the second terminal comprises applying an electrical ERASE pulse with a polarity such that a reactive electrode contacting the resistive storage medium is negatively biased with respect to an inert electrode contacting the resistive storage medium.

24. The method of claim 23, further comprising at least partly removing an electrically conductive pathway within the resistive storage medium between the reactive electrode and the inert electrode.

25. The method of claim 24, wherein at least partly removing the electrically conductive pathway comprises increasing an electrical resistance of the resistive storage medium from a value smaller than an electrical resistance of the resistance element to a value greater than the electrical resistance of the resistance element.

26. The method of claim 19, wherein applying the electrical operation signal between the first terminal and the second terminal comprises applying an electrical READ signal, and wherein the method comprises determining a resistance state of an electrical resistance between the first and second terminal.

27. The method of claim 26, wherein the electrical READ signal is applied with a polarity such that a reactive electrode contacting the resistive storage medium is positively biased with respect to an inert electrode contacting the resistive storage medium.

28. A system comprising:
an input apparatus;
an output apparatus;
a processing apparatus; and
a memory, said memory comprising a storage cell, the storage cell comprising:
a resistive storage medium that is switchable between at least a high resistive state and a low resistive state; and
a resistance element communicatively coupled to the resistive storage medium in series.

29. The system of claim 28, wherein the memory comprises a plurality of storage cells arranged in rows and columns of at least one array, wherein each storage cell comprises
a resistive storage region switchable between at least a high resistive state and a low resistive state;
a resistance element; and
a select device, wherein the resistive storage region, the resistance element and the select device are communicatively coupled in series in the storage cell, and wherein the memory further comprises:
a word line for each row, the word line being communicatively coupled to at least some of the storage cells in the respective row; and
a bit line for each column, the bit line being communicatively coupled to at least some of the storage cells in the respective column.
